(19) United States
(12) Patent Application Publication
(10) Pub. No.: US 2007/0295063 A1
(43) Pub. Date: Dec. 27, 2007

(54) APPARATUS FOR MANUFACTURING A SEMICONDUCTOR AND A METHOD FOR MEASURING THE QUALITY OF A SLURRY

(75) Inventors: Hyun-Chan CHO, Gyeonggi-do (KR); Sang-Gon LEE, Gyeonggi-do (KR); Sang-Yeoul HWANG, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/768,768

(22) Filed: Jun. 26, 2007

(30) Foreign Application Priority Data
Jun. 26, 2006 (KR) 2006-57699

(51) Int. Cl. G01N 15/02; H01L 21/66

(52) U.S. Cl. 73/61.71; 29/25.01; 438/14; 73/865.5

(57) ABSTRACT

A method for manufacturing a semiconductor and an apparatus for measuring slurry quality. The apparatus includes a plurality of slurry supply devices, a plurality of semiconductor processing devices, and an in-line monitoring system. The slurry supply devices have slurry supply lines. The semiconductor processing devices receive slurry from each of the slurry supply devices through the slurry supplying lines to perform semiconductor processing. The in-line monitoring system includes a plurality of sampling lines diverging from the plurality of slurry supplying lines. The particle sizes of the slurry are measured through each of the sampling lines. The monitoring system maintains the slurry quality in real time to increase yield from CMP (chemical-mechanical polishing).

### CROSS-REFERENCE TO RELATED APPLICATIONS

This U.S. non-provisional patent application claims priority under 35 U.S.C. §119 of Korean Patent Application No. 2006-57699, filed on Jun. 26, 2006, the entire contents of which are hereby incorporated by reference.

### BACKGROUND OF THE INVENTION

The present invention disclosed herein relates to an apparatus for manufacturing semiconductors and a method for measuring the quality of a slurry, and more particularly, to an apparatus for manufacturing semiconductors and a method for measuring the quality of a slurry that are capable of reducing defects of chemical-mechanical polishing.

Due to today's demands for increasingly high integration and density in the semiconductor industry, techniques for forming finer patterns are being used, and fields requiring multi-level wiring structures are increasing. Accordingly, semiconductor device structures are becoming more complex. An example of this complexity is the increased severity of stepped degrees of interlayer films.

Severe stepping of interlayer films may generate process defects during semiconductor manufacturing. To remove such defects, techniques such as SOG, etch back, reflow, and chemical-mechanical polishing (CMP) for regional planarization have been developed. In a CMP process, the removal rate and uniformity are crucial factors, along with slurry type, polishing pad type, and so on.

Slurry, which mechanically forces polishing compounds onto the surface of a wafer, generally consists of polishing particles, ultra-pure water, and additives. Slurries use physical, chemical, and mechanical principles involving agglomerations of particles. CMP using agglomerated slurry particles produces defects on the surface of the wafer, such as micro scratches, reducing production yield. These defects are known to be caused by the inclusion of undesirable particles that are excessively large (or coarse).

Coarse particles may form in slurry from smaller particles agglomerating. This is a phenomenon that continues to occur even after the slurry is correctly manufactured. Agglomerating particles are due to the constant motion of all particles within the slurry after its manufacture. Thus, performing CMP has always involved large drawbacks. There is always the possibility of introducing a new slurry that has already agglomerated, perhaps during the transport and supply stage. In addition, many external factors such as temperature, outside impurities, aging, and so on can deteriorate the quality of slurry. Comprehensive examinations of micro-scratch occurrences (one of the major defects that can arise in a CMP process) show that coarse particles from various sources (approx. 1 μm or larger) are among the principle causes.

### SUMMARY OF THE INVENTION

The present invention provides a solution to these problems by monitoring the degree of coarse particle formation on slurry supply equipment, preferably in real time, in order to maintain slurry quality and prevent the introduction of low-quality slurry.

An embodiment of the present invention provides a semiconductor manufacturing apparatus and a method of measuring quality of slurry. The apparatus and method are capable of managing the quality of slurry and reducing defects during a chemical-mechanical polishing process.

To achieve these objects of the present invention, there are provided semiconductor manufacturing apparatuses and methods for measuring the quality of the slurry that include a slurry quality monitoring system connected in-line to a plurality of slurry supply devices to monitor the quality of the slurry in real time.

In an embodiment, an apparatus for manufacturing a semiconductor may comprise: a plurality of slurry supply devices each having a slurry supply line; a plurality of semiconductor processing devices for receiving slurry from each of the slurry supply devices through the slurry supply line; and an in-line monitoring system including a plurality of sampling lines connected to the plurality of slurry supply lines, the in-line monitoring system configured to measure particle sizes of the slurry. The in-line monitoring system may comprise a particle size analyzer for diluting the slurry and measuring the number and sizes of slurry particles.

In another embodiment the particle size analyzer may comprise: a diluting device for diluting the slurry with a diluent; a sample loop for mixing the slurry with the diluent; a pump for generating a predetermined pressure to provide the diluent to the sample loop at a predetermined flow rate; and a sensor for receiving diluted slurry from the diluting device and measuring the number and sizes of the slurry particles.

In still another embodiment, a method for measuring slurry quality may comprise: supplying slurry from a plurality of slurry supply devices to a plurality of semiconductor processing devices through a plurality of slurry supply lines; providing the supplied slurry to a particle size analyzer through a sampling line connected to one of the slurry supplying lines; and diluting the slurry provided to the particle size analyzer to measure slurry particle sizes.

The method may further comprise: cleaning the sampling line by providing a cleaning solution to the sampling line while not providing the slurry to the sampling line; and providing the cleaning solution to the particle size analyzer to measure the number and sizes of the slurry particles mixed with the cleaning solution.

In yet another embodiment, measuring the particle sizes of the slurry may comprise: providing the slurry to a sample loop to mix deionized water with the slurry provided to the sample loop; providing the slurry mixed with the deionized water to a diluting device; diluting the slurry; and providing the diluted slurry to an optical sensor to measure the number and sizes of the slurry particles.

### BRIEF DESCRIPTION OF THE FIGURES

The accompanying figures are included to provide a further understanding of the present invention, and are incorporated in and constitute a part of this specification. The drawings illustrate exemplary embodiments of the present invention and, together with the description, serve to explain principles of the present invention. In the figures:

FIG. 1 is a schematic block diagram of a semiconductor manufacturing apparatus illustrating various aspects and embodiments of the present invention:

FIG. 2 is a schematic cross-sectional diagram showing details of the slurry supply device of the semiconductor manufacturing apparatus of FIG. 1, according to some embodiments of the present invention;

FIGS. 3 through 5 are schematic diagrams showing supply-line flow details for various valve settings, according to further aspects of the present invention;

FIG. 6 is a schematic block diagram of a particle size analyzer used in a semiconductor manufacturing apparatus according to further aspects of the present invention;

FIG. 7 is a graph demonstrating reproducibility of measurements of a semiconductor manufacturing apparatus according to principles of the present invention; and

FIG. 8 is a schematic block diagram of a semiconductor manufacturing apparatus according to still other embodiments of the present invention.

### DETAILED DESCRIPTION OF PREFERRED EMBODIMENTS

Preferred embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Like reference numerals refer to like elements throughout.

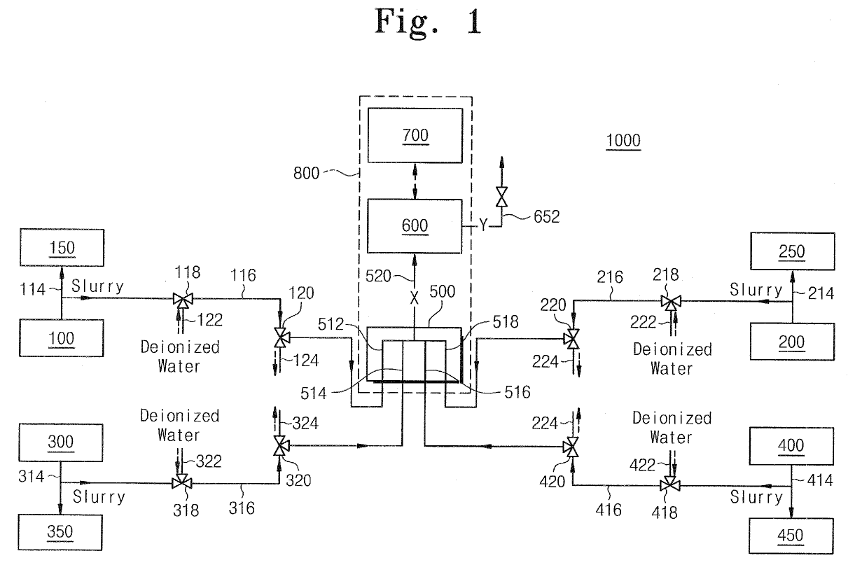

FIG. 1 is a schematic of a semiconductor manufacturing apparatus according to embodiments of the present invention.

Referring to FIG. 1, a semiconductor manufacturing apparatus 1000 is configured to apply the slurry onto a semiconductor wafer and to perform a chemical-mechanical polishing process (CMP). The apparatus 1000 of this embodiment may be provided with an in-line monitoring system 800 for measuring the quality of the slurry, which may be connected to four slurry supply devices 100, 200, 300, and 400. Each of the four slurry supply devices 100-400 is configured to supply the slurry to polishers 150, 250, 350, and 450, respectively. The in-line monitoring system 800 may receive the slurry from the four slurry supply devices 100-400 through sampling lines 116, 216, 316, and 416, and measure the particle size of the slurry for each of the slurry supply devices 100-400.

Regarding some of the embodiments of the present invention described herein, “measuring the particle size of the slurry” generally means measuring the number of slurry particles in size categories and evaluating the quality of the slurry. When the slurry particle size measurements show that there are coarse slurry particles present that may cause micro scratches to a wafer during CMP, the slurry quality may be determined to be defective, and when the measurements do not show such particles present, the slurry may be determined to be of good quality. The “particles” described herein refer to particles that have the potential to inflict micro scratches on a wafer.

The apparatus 1000 provided with the in-line monitoring system 800 for measuring slurry quality for each of the slurry supply devices 100-400 will now be explained in detail. It should be noted that the description provided below of the slurry supply device 100 and the sampling line 116 may be representative of the other slurry supply devices 200-400 and sampling lines 216-416.

The slurry supply device 100 may supply the slurry used for CMP by transporting it in its undiluted state to a polisher that is the point of use (POU). The slurry may undergo various processes according to slurry type. The slurry supply device 100 may provide the slurry by storing it in its undiluted state in a drum and supplying it to the polisher 150 through a slurry supplying line 114. The sampling line 116 that provides the slurry for sampling to the in-line monitoring system 800 may be connected to the slurry supplying line 114. Before the slurry is provided to the polisher 150 in its undiluted state, the sampling line 116 is structured to bypass the slurry from the slurry supplying line 114.

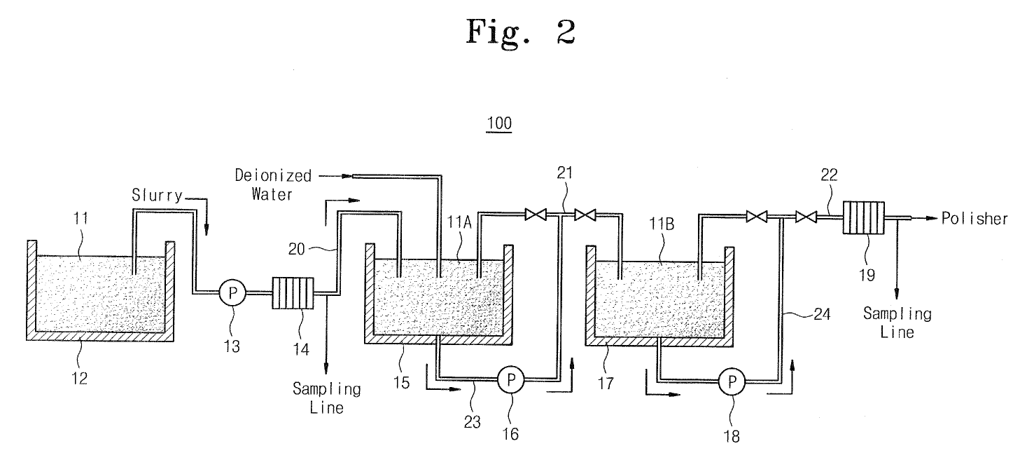

FIG. 2 is a schematic cross-sectional diagram showing details of the slurry supply device 100 of the semiconductor manufacturing apparatus 1000 of FIG. 1, according to various embodiments of the present invention.

Referring to FIG. 2, the slurry supply device 100 may include a drum 12 that stores undiluted slurry 11, a mixing tank 15 for mixing the undiluted slurry 11 with deionized water, and a storage tank 17 that stores and provides a slurry mixture 11A of the slurry and the deionized water to the polisher 150. The undiluted slurry 11 may flow through a slurry supply line 20 by means of a pump 13, and may be filtered by a filter 14 and transferred to the mixing tank 15. The undiluted slurry 11 may be mixed with the deionized water in the mixing tank 15. To attain a uniform slurry mixture 11A, the slurry mixture 11A may be circulated through a circulating line 23 by the operation of a pump 16. The slurry mixture 11A may be transferred to the storage tank 17 through a slurry supply line 21, and circulated around a circulating line 24 to prevent its degeneration. Supply slurry 11B stored in the storage tank 17 may be supplied by flowing through a supply line 22 and filtered by a filter 19.

In the above-described slurry supply apparatus 100, the sampling line 116 (FIG. 1) may be installed in such a way that the slurry is not subject to effects from stress, flow quantity, pressure, etc. For example, the sampling line 116 may be formed on the slurry supply line 20 that transfers the undiluted slurry 11 from the slurry drum 12 to the mixing tank 15. Also, the sampling line 116 may be located after the filtering by the filter 19 and before the supplying to the polisher, as shown in FIG. 2.

Referring again to FIG. 1, the sampling line 116 may be formed to allow its inside to be cleaned. For instance, two 3-way valves 118 and 120 may be installed on the sampling line 116. The 3-way valve 118 may have an inflow line 122 connected thereto for providing deionized water to the sampling line 116, and the other 3-way valve 120 may have an outflow line 124 for discharging the deionized water from the sampling line 116. The deionized water may be used as a cleaning solution for cleaning the inside of the sampling line 116. The slurry that passes through the sampling line 116 may be supplied to the in-line monitoring system 800 for performing quality inspection of a sample thereof, and the deionized water that cleans the inside of the sampling line 116 may be provided to the in-line monitoring system 800 to measure the cleanliness of the inside of the sampling line 116.

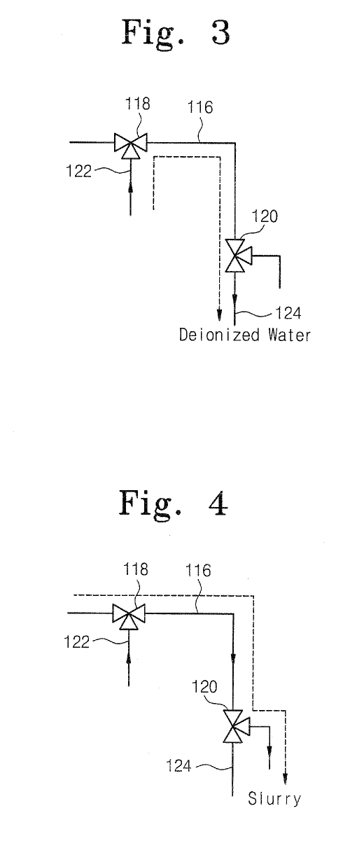

FIGS. 3 through 5 are schematics showing supply-line flow details for various valve settings, according to embodiments of the present invention.

Referring to FIG. 3, the 3-way valves 118 and 120 may be controlled to prevent the slurry from being supplied into the sampling line 116 while deionized water is being supplied through the inflow line 122 into the sampling line 116 and then discharged through the outflow line 124. In this fashion, the deionized water can clean the sampling line 116 to prevent impurities from entering the slurry when it flows through the sampling line 116. The sampling line 116 may be cleaned before and after a quality measurement of the slurry.

Referring to FIG. 4, the 3-way valves 118 and 120 may be controlled to prevent the deionized water from being supplied into the sampling line 116 while enabling the slurry to flow through the sampling line 116. Thus, the slurry may be supplied to the in-line monitoring system 800 to determine whether its quality is good or defective.

Referring to FIG. 5, to measure the degree of cleanliness of the sampling line 116 (which may, for example, be represented by the number of particles inside the sampling line 116), the 3-way valves 118 and 120 are controlled to prevent the slurry from being supplied into the sampling line 116 while supplying the deionized water through the inflow line 122 into the sampling line 116. Here, the outflow line 124 is closed and the deionized water is supplied into the in-line monitoring system 800. Monitoring the degree that the slurry is agglomerated within the sampling line 116 may be used to determine when the slurry supplying apparatus 100 including the sampling line 116 should be cleaned.

Referring again to FIG. 1, the in-line monitoring system 800 may be configured to measure the number of particles from the slurry sample. The in-line monitoring system 800 may include a multi-line junction 500, a particle size analyzer 600, and a controller 700. The slurry flowing through the sampling line 116 may be supplied through the multi-line junction 500 to the in-line monitoring system 800. The multi-line junction 500 receives lines 512, 514, 516, and 518, which are respectively connected to the four sampling lines 116, 216, 316, and 416 to receive the slurry. The slurry that passes through the multi-line junction 500 may be supplied to the particle size analyzer 600 to measure its quality. The particle size analyzer 600 may first dilute the slurry to measure the size and number of particles mixed in the slurry.

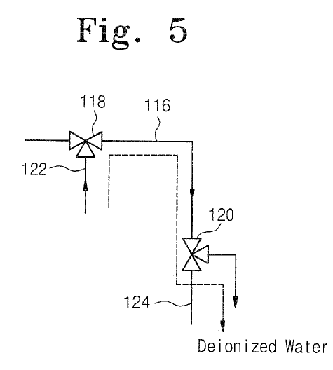

FIG. 6 is a structural diagram of a particle size analyzer in a semiconductor manufacturing apparatus according to embodiments of the present invention.

Referring to FIG. 6, the slurry that is supplied through a line 520 from the multi-line junction 500 may be mixed with a diluent that passes through a diluent inflow line 604 in a sample loop 620, to be diluted and then supplied to a first diluting device 630 through a line 622. The diluent may be deionized water, which may be supplied to the sample loop 620 at a uniform flow rate through a line 612 by means of a uniform pressure generated by a diluent pump 610. Accordingly, the slurry mixed with the deionized water in the sample loop 620 may also receive a uniform pressure, from a diluent pump 610, to flow at a constant flow rate to be diluted and subsequently supplied to the first diluting device 630. Diluting the slurry with the deionized water makes it easier to measure the size and number of particles mixed in the slurry.

The slurry that is diluted in the first diluting device 630 may be discharged through a line 632 and may be supplied to a second diluting device 640 to be diluted further. This additional diluting may be performed by supplying deionized water through a line 634 to the second diluting device 640. The slurry that is re-diluted by the second diluting device 640 may be discharged through a line 642 and then supplied to a sensor 650. The sensor 650 may be configured to measure the number of particles mixed in the diluted slurry, for example, particles that are approximately 1 μm or larger, which are liable to cause micro-scratches on a wafer that is to be polished. The sensor 650 may, for example, use light extinction/scattering to sense particles' presence and size. The sensor 650 may output a result to the controller 700 (FIG. 1). Such sensors are well-known in the art and may include, for instance, a single particle optical sensing sensor.

The diluted slurry that has been sampled may be drained through a line 652. Lines 602 and 624 may be used to flush the slurry from the particle size analyzer 600. The lines 602 and 624 may drain the slurry if an error occurs in an initial setting of the particle size analyzer 600.

The controller 700 may be configured to control the particle size analyzer 600 according to a set of parameters, such as the amount of desired diluting, the sampling duration, data collecting duration, the flow speed of the diluent, the volume of the sample loop, the flush duration, and the like. The controller 700 may control the operation of the slurry supply devices 100-400 and the polishers 150-450 based on the data monitored by the particle size analyzer 600. In this fashion, the controller 700 may prevent defective slurry from being supplied to the polishers 150-450 so that the occurrence of micro scratches during CMP is prevented.

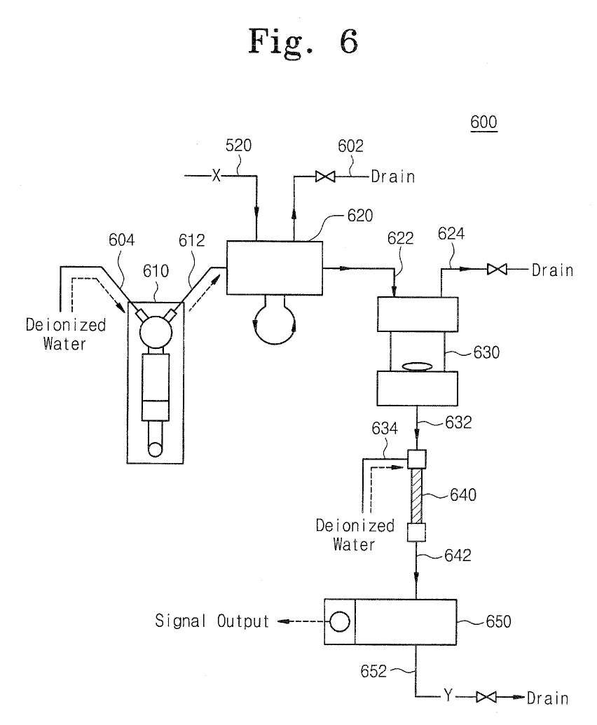

FIG. 7 is a graph demonstrating reproducibility of measurements in a semiconductor manufacturing apparatus according to embodiments of the present invention.

Referring to FIG. 7, the graph displays the results of measurements performed by the in-line monitoring system 800 as circular dots, and displays the results measured by an off-line particle size analyzer as square points. When the in-line measurement results and the off-line measurement results are compared, it can be seen that they are almost identical. That is, the results measured by the in-line monitoring system 800 are accurate.

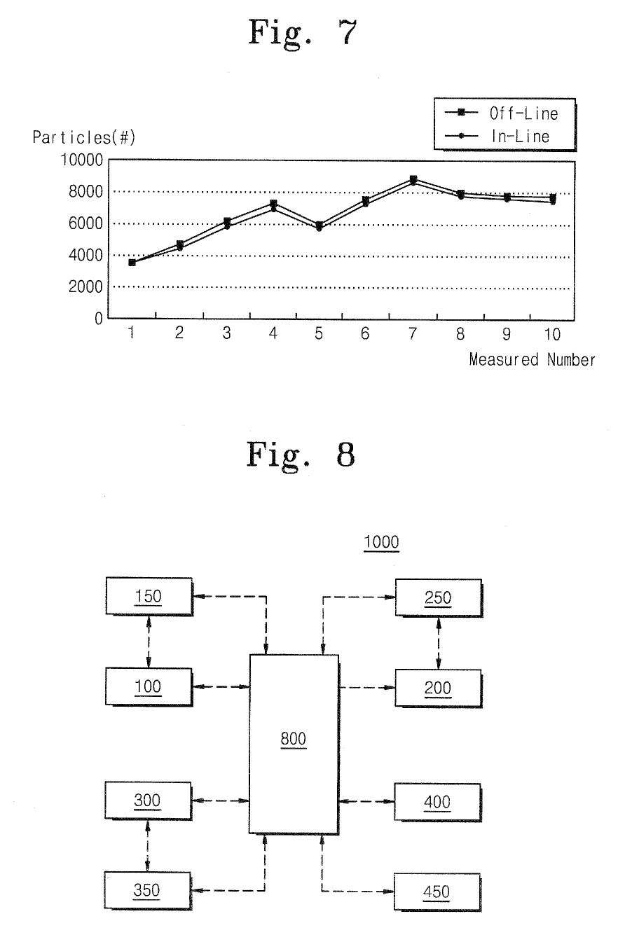

FIG. 8 is a structural schematic block diagram of a semiconductor manufacturing apparatus according to embodiments of the present invention.

Referring to FIG. 8, the slurry supply devices 100-400, the polishers 150-450, and the in-line monitoring system 800 may be connected to communicate with one another and share data through wires or wirelessly. When the particle size of the slurry appears to exceed a predetermined particle size, the controller 700 may perform a controlling function that prevents further slurry from being introduced to the polishers 150-450. This poor slurry stored in the slurry supply devices 100-400 may then be drained in its entirety, and new slurry may then be supplied.

The above-structured semiconductor manufacturing apparatus may be used to perform a slurry quality assessment as described below.

Referring to FIG. 1, the sampling line 116 that branches from the slurry supplying line 114 may be cleaned with deionized water before and after slurry quality measurements are performed. The cleaning of the sampling line 116 may be performed while not supplying the slurry into the sampling line 116, and instead supplying the deionized water to the sampling line 116 through the line 122, and then draining the deionized water through the line 124, by controlling the 3-way valves 118 and 120, as depicted in FIG. 3.

To measure the quality of the slurry, as shown in FIG. 4, deionized water may be prevented from being supplied into the sampling line 116, and instead the slurry may be supplied into the sampling line 116 and then transferred to the multi-line junction 500, by controlling the opening and closing of the 3-way valves 118 and 120. In this case, the slurry may pass through the multi-line junction 500 and be supplied to the particle size analyzer 600. The slurry supplied to the particle size analyzer 600, as shown in FIG. 6, may be diluted by the deionized water in the first and second diluting devices 630 and 640. Meanwhile, the diluted slurry may be supplied to the sensor 650 to measure the number and size of the slurry particles. The diluent pump 610 may be provided with the particle size analyzer 600 to generate a predetermined pressure and flow rate of the slurry and deionized water that flows through the particle size analyzer 600.

When the number or size of particles within the slurry is detected to exceed a set value, the slurry waiting to be used in the slurry supply device 100 may be drained and replaced with fresh slurry. Slurry quality may be measured in real time, and each of the slurry supply devices 100-400 may be separately controlled. Also, data for the slurry supplied from the in-line monitoring system 800 may be used to analyze details of the reasons for micro scratch occurrence during CMP processes.

As shown in FIG. 5, to monitor the degree of cleanliness of the sampling pipe 116, the 3-way valves 118 and 120 may be controlled to withhold the supply slurry from the sampling line 116, and instead supply deionized water into the sampling line 116 through the line 122 to the multi-line junction 500. The particles within the sampling line 116 may be supplied to the particle size analyzer 600 by passing through the multi-line junction 500. By measuring the number of particles mixed with the deionized water in the particle size analyzer 600, the degree of cleanliness of the sampling line 116 can be measured. When the degree of cleanliness of the sampling line 116 satisfies a desired level, the quality of the slurry may then be measured. As described above, the number and size of particles within the sampling line 116 may be checked and, based on the results, the time for cleaning the slurry supply device 100 can be determined.

As described above in this detailed description, the occurrence of micro scratches during CMP can be anticipated and prevented by supplying slurry after a distribution analysis of particles in the slurry is performed. Therefore, the quality of the slurry can be maintained, and yield from a CMP process can be increased.

The above-disclosed subject matter is to be considered illustrative, and not restrictive, of the present invention, and the appended claims are intended to cover all modifications, enhancements, and other embodiments, that fall within the true spirit and scope of the present invention. The scope of the present invention should therefore be determined by giving the claims their broadest permissible interpretation including their equivalents, and should not be restricted or limited by the foregoing detailed description.

What is claimed is:

1. An apparatus for manufacturing a semiconductor, comprising:
a slurry supply device having a slurry supply line;
a semiconductor processing device for receiving slurry from of the slurry supply device through the slurry supply line; and
an in-line monitoring system including a sampling line connected to the slurry supply line, the in-line monitoring system configured to measure a number, size, or both of particles in the slurry.

2. The apparatus of claim 1, wherein the sampling line comprises an inflow line for providing a cleaning solution to the sampling line and an outflow line for discharging the cleaning solution.

3. The apparatus of claim 2, wherein the inflow line is connected to the sampling line by a first 3-way valve and the outflow line is connected to the sampling line by a second 3-way valve.

4. The apparatus of claim 2, wherein, to clean the sampling line, the cleaning solution is supplied through the inflow line to the sampling line, and is drained through the outflow line.

5. The apparatus of claim 2, wherein the cleaning solution is supplied through the inflow line to the sampling line and provided to the in-line monitoring system, and the in-line monitoring system is configured to measure at least the number or size of slurry particles mixed in the cleaning solution.

6. The apparatus of claim 1, wherein the in-line monitoring system comprises a particle size analyzer for diluting the slurry and measuring at least the number or size of slurry particles.

7. The apparatus of claim 6, wherein the particle size analyzer comprises:
a diluting device for diluting the slurry with a diluent;
a sample loop for mixing the slurry with the diluent;
a pump for generating a predetermined pressure to provide the diluent to the sample loop at a predetermined flow rate; and
a sensor for receiving diluted slurry from the diluting device and measuring the number and size of the slurry particles.

8. The apparatus of claim 7, wherein the diluting device comprises:
a first diluting device for diluting the slurry mixed with the diluent in the sample loop; and
a second diluting device for further diluting the slurry diluted in the first diluting device.

9. The apparatus of claim 6, wherein the in-line monitoring system comprises:
a multi-line junction connected to a plurality of sampling lines, and configured to receive slurry from each of the sampling lines and for providing the received slurry to the particle size analyzer; and
a controller for controlling the particle size analyzer.

10. The apparatus of claim 9, wherein the slurry supply device, the semiconductor processing device and the in-line monitoring system are interconnected through a wired or wireless connection to be capable of communicating with each other, and wherein the controller controls the slurry supply device and the semiconductor processing device, based on data analyzed by the particle size analyzer.

11. A method for measuring slurry quality, comprising:
supplying slurry from a slurry supply device to a semiconductor processing device through a slurry supply line;
providing the supplied slurry to a particle size analyzer through a sampling line connected to the slurry supplying lines; and
diluting the slurry provided to the particle size analyzer to measure slurry particle sizes.

12. The method of claim 11, further comprising cleaning the sampling line by providing a cleaning solution to the sampling line while not providing the slurry to the sampling line.

13. The method of claim 12, wherein cleaning the sampling line comprises:
providing deionized water to an inflow line connected to the sampling line; and
draining the deionized water from an outflow line connected to the sampling line.

14. The method of claim 11, further comprising:
cleaning the sampling line by providing a cleaning solution to the sampling line while not providing the slurry to the sampling line; and
providing the cleaning solution to the particle size analyzer to measure the number and sizes of the slurry particles mixed with the cleaning solution.

15. The method of claim 14, wherein cleaning the sampling line comprises:
providing deionized water to an inflow line connected to the sampling line;
closing an outflow line connected to the sampling line; and
providing the deionized water to the particle size analyzer.

16. The method of claim 11, wherein measuring the particle sizes of the slurry comprises:
providing the slurry to a sample loop to mix deionized water with the slurry provided to the sample loop;
providing the slurry mixed with the deionized water to a diluting device;
diluting the slurry; and
providing the diluted slurry to an optical sensor to measure the number and size of the slurry particles.

17. The method of claim 16, wherein providing the slurry mixed with the deionized water to the diluting device comprises providing the slurry mixed with the deionized water at a predetermined flow rate to the diluting device using a diluting pump.

18. The method of claim 17, wherein providing the slurry mixed with the deionized water to the diluting device comprises:
providing slurry mixed with deionized water in the sample loop to a first diluting device to dilute the slurry;
providing the slurry diluted in the first diluting device to a second diluting device; and
providing the deionized water to the second diluting device to further dilute the slurry.

19. The method of claim 16, further comprising draining the diluted slurry from the optical sensor after measuring the number and size of the slurry particles.

20. The method of claim 11, wherein providing the supplied slurry to the particle size analyzer comprises:
providing the slurry to a multi-line junction connected to a plurality of sampling lines, the multi-line junction configured to receive the slurry from each of the sampling lines; and
providing the slurry to the particle size analyzer from the multi-line junction.

21. An apparatus for manufacturing a semiconductor, comprising:
a plurality of slurry supply devices, each having a slurry supply line;
a plurality of semiconductor processing devices, each connected to a respective slurry supply line to receive slurry from a respective one of the slurry supply devices;
a plurality of sampling lines connected to respective ones of the slurry supply lines; and
a slurry monitoring device configured to monitor the slurry for defective composition.
